(19) United States
(12) Patent Application Publication
(10) Pub. No.: US 2019/0368822 A1
(43) Pub. Date: Dec. 5, 2019

(54) Cooling Device Having a Heat Pipe and a Latent Heat Store

(71) Applicant: Siemens Aktiengesellschaft, München (DE)

(72) Inventors: Oliver Hofacker, Berlin (DE); Olaf Rehme, Hamburg (DE); Daniel Reznik, Berlin (DE)

(73) Assignee: Siemens Aktiengesellschaft, München (DE)

(21) Appl. No.: 16/477,625

(22) PCT Filed: Dec. 15, 2017
(86) PCT No.: PCT/EP2017/082958

§ 371 Date: Jul. 12, 2019

(30) Foreign Application Priority Data
Jan. 13, 2017 (DE) 10 2017 200 524.6

(51) Int. Cl. F28D 15/02; F28D 20/02; H05K 7/20; H01L 23/427

(52) U.S. Cl. CPC F28D 15/0275; F28D 20/023; H01L 23/427; H05K 7/20936; H05K 7/20336

(57) ABSTRACT

Various embodiments include a cooling apparatus comprising: a thermal interface for a heat source to be cooled; a thermal pipe with a first phase change medium; and a latent heat store with a second phase change medium. The first phase change medium and the second phase change medium are contained in respective volumes separated from one another. Heat of the heat source, at the thermal interface, transfers into a heat absorption zone of the thermal pipe. A melting temperature of the second phase change medium is greater than an evaporation temperature of the first phase change medium.

### CROSS-REFERENCE TO RELATED APPLICATIONS

This application is a U.S. National Stage Application of International Application No. PCT/EP2017/082958 filed Dec. 15, 2017, which designates the United States of America, and claims priority to DE Application No. 10 2017 200 524.6 filed Jan. 13, 2017, the contents of which are hereby incorporated by reference in their entirety.

### TECHNICAL FIELD

The present disclosure relates to cooling apparatus with phase change heat stores. Various embodiments include a thermal interface for a heat source to be cooled.

### BACKGROUND

In some devices, there is a thermal interface designed in the form of a heat transfer surface bearing with this against the heat source to be cooled. A cooling apparatus is known for example from DE 20 2015 004 833 U1. The cooling arrangement, described therein, for cooling a technical device has a metal container which is filled with a phase change medium serving as a latent heat-storing material (phase change material). A thermal pipe furthermore extends in the container, by way of which thermal pipe the intention is to transport heat from the phase change material of the latent heat store out of the housing.

DE 20 2015 004 833 U1 describes as an application for the cooling device the possibility of cooling a technical device without use of energy during the daytime by storing generated heat by way of a phase change of the phase change material from solid to liquid. At night, said heat can be released to the surroundings via the thermal pipe owing to the cooling of the ambient air.

DE 10 2013 217 829 A1 describes use of latent heat stores for improving the cooling power of coolers in the event of the occurrence of load peak, for example in the case of electronic circuits. The phase change material is able to absorb the generated heat associated with load peaks in that the phase change medium undergoes a phase change from solid to liquid, that is to say melts. Said heat can be released at a later stage via the cooler by way of solidification of the phase change medium when the actual heat source generates less heat.

The latter solution provides the cooling power of the cooling system can be, not for the occurrence of load peaks, but for continuous use. In this way, it is possible for the cooling system to be designed in a more compact and lighter manner overall. Examples of applications of such cooling systems are the power electronics in the case of switching operations and converters of electric motors, which have to produce high power in a short time (load peaks), such as for example in the case of electrical flight during the climbing flight phase. Here, the quantity of heat generated under the load peak has to be taken into account in order to determine the required heat capacity of the latent heat store.

The heat conductivity of phase change media, such as salts or paraffins, is limited, however. In order to achieve a more rapid input of heat into the phase change medium, EP 2 236 970 A1 describes a heat-conducting structure consisting of a three-dimensional spatial lattice be arranged in the phase change medium. Via said spatial lattice, which provides a large surface for transfer of heat, it is possible for the heat to be released to the surroundings of the latent heat store more rapidly.

### SUMMARY

The teachings of the present disclosure describe a cooling apparatus and an electronic circuit in which cooling (heat removal) is possible with relatively little material outlay (that is to say by way of light and compact structures). For example, some embodiments include a cooling apparatus having a thermal interface for a heat source to be cooled, wherein the cooling apparatus has a thermal pipe (15), with a first phase change medium (20), and a latent heat store (17), with a second phase change medium (22), in volumes separated from one another, characterized in that the heat of the heat source is, at the thermal interface, able to be introduced into a heat absorption zone of the thermal pipe (15), and the melting temperature of the second phase change medium (22) is greater than the evaporation temperature of the first phase change medium (20).

In some embodiments, the melting temperature of the second phase change medium (22) is less than 20 K, or less than 10 K, greater than the evaporation temperature (20) of the first phase change medium.

In some embodiments, the thermal pipe (15) and the latent heat store (17) are formed by two spatial structures nested one inside the other.

In some embodiments, the latent heat store (17) is formed by a hollow spatial lattice, wherein the second phase change medium (22) is enclosed in a hollow space which is formed as a latent heat store (17) in the spatial lattice, and the first phase change medium (20) is accommodated in lattice intermediate spaces formed by the lattice.

In some embodiments, the latent heat store has a multiplicity of partial spaces (17a, 17b, 17c), which are held in the thermal pipe (15).

In some embodiments, the partial spaces (17a, 17b, 17c) are fluidically connected to one another.

In some embodiments, there are multiple thermal pipes (15), which are surrounded by the latent heat store (17).

In some embodiments, in a heat release zone (18), the at least one thermal pipe (15) is provided on the outside with a passive cooling structure (19a, 19b).

In some embodiments, the passive cooling structure (19a, 19b) has ribs and/or a spatial lattice.

In some embodiments, the at least one thermal pipe (15) is designed in one piece with a capillary wall structure (21) in the form of a heat pipe.

In some embodiments, a heat-conducting structure (24a, 24b) is arranged in the latent heat store (17) and is connected to the wall of the latent heat store (17).

In some embodiments, the heat-conducting structure (24a, 24b) has ribs and/or a spatial lattice.

In some embodiments, the structural component (13) is connected to the thermal interface of a cooling apparatus (14) as described above.

In some embodiments, the maximum possible cooling power of the thermal pipe (15) of the cooling apparatus (14) is greater than or equal to the heating power of the structural component (13) at rated load, but is less than the heating power of the structural component (13) at a permitted peak load.

As another example, some embodiments include a method for producing a cooling apparatus (14) as described above, characterized in that an additive manufacturing process, in particular a laser melting process or a combination of laser sintering and laser melting, is used for production. In some embodiments, this is produced using an additive manufacturing process, in particular a laser melting process or a combination of laser sintering and laser melting.

In some embodiments, the apparatus is produced in one piece.

### BRIEF DESCRIPTION OF THE DRAWINGS

Further details of the teachings herein are described below on the basis of the drawings. Identical or corresponding elements of the drawing are provided in each case with the same reference signs and will be discussed multiple times only where differences exist between the individual figures. In the drawings:

FIG. 1 shows, in section, an exemplary embodiment of the cooling apparatus incorporating teachings of the present disclosure with multiple thermal pipes in different variants,

FIG. 2 shows, in section, an exemplary embodiment of the cooling apparatus incorporating teachings of the present disclosure with a latent heat store which consists of multiple partial spaces,

FIG. 3 shows, in section, an exemplary embodiment of the cooling apparatus incorporating teachings of the present disclosure with a latent heat store designed in the form of a hollow lattice,

FIG. 4 shows, in section, the detail IV from FIG. 3, and

FIG. 5 shows an exemplary embodiment of a method incorporating teachings of the present disclosure.

### DETAILED DESCRIPTION

In some embodiments, the melting temperature of the second phase change medium is greater than the evaporation temperature of the first phase change medium. In some embodiments, during the normal operation of the cooling apparatus, only the first phase change medium in the thermal pipe comes into play. In this case, the heat is introduced into a heat absorption zone of the thermal pipe via the thermal interface, leads to the evaporation of the first phase change medium there, and, in a heat release zone, is released to the surroundings with simultaneous condensation of the first phase change medium. Thus, during normal operation, the cooling apparatus does not heat up to such an extent that melting of the second phase change medium in the latent heat store occurs, since the melting temperature of the second phase change medium is above the evaporation temperature of the first phase change medium.

In some embodiments, the heat capacity of the latent heat store is therefore available as a reserve, for example for the effective cooling of load peaks or for avoiding unstable operating states in the thermal pipe. In the latent heat store, the heat generated during a load peak is temporarily stored as melt heat. Falling of the temperature in the cooling apparatus back to below the melting temperature of the second phase change medium after the load peak has subsided results in the heat being released to the thermal pipe during the solidification of said second phase change medium. In other words, in this operating state, the thermal pipe simultaneously serves for cooling the latent heat store and cooling the actual heat source to be cooled.

Overall, it is not therefore necessary for the heat removal power of the thermal pipe to be designed for the occurrence of load peaks of the heat source. In order to accommodate said load peaks, the latent heat store is available according to the invention. However, the heat removal power of the thermal pipe has to ensure that, during normal operation, the heat which is stored in the latent heat store if load peaks occur can additionally be removed. Overall, it is thus possible for the cooling apparatus to be designed in a more compact and lighter manner, wherein the additional outlay for the latent heat store is more than compensated by the savings with the thermal pipe.

In some embodiments, two temperatures are relevant. For operation under normal conditions, the temperature at which the function of the thermal pipe takes effect is important. This temperature is predefined by the boiling temperature of the first phase change medium enclosed in the thermal pipe. The second temperature is the melting temperature of the second phase change medium. This temperature, in case of need, is stabilized by the enthalpy of fusion, to be applied, of the second phase change medium, and for this reason, within the context of the capacity of the latent heat store, the temperature of the cooling apparatus does not increase further. The design of the latent heat store has to be realized such that, in the event of load peaks, a sufficient heat capacity of the latent heat store is provided. The effect of the latent heat store is limited to the duration until the second phase change medium has been completely melted.

A thermal pipe is a heat transfer means which uses the evaporation heat of the first phase change medium for heat transport. In a heat absorption zone of the thermal pipe, the first phase change medium evaporates and cools said zone owing to the evaporation heat required for this process. In a heat release zone of the thermal pipe, the first phase change medium condenses and, in this region, releases the evaporation heat to the surroundings. For this function, a design which allows for a heat absorption zone and a heat release zone is required. In this case, it is not absolutely necessary for the geometry of the thermal pipe to be tubular. The term “thermal pipe” refers merely to a particular functioning for cooling, with the thermal pipe providing a volume for accommodating the first phase change material, which is sealed off with respect to the surroundings. The thermal pipe may comprise a thermosiphon, wherein the heat release zone is situated geodetically above the heat absorption zone, with the result that the evaporated first phase change medium can rise upward in order to condense there and, in a liquid state, run downward again.

In some embodiments, the thermal pipe comprises a heat pipe. In this case, the heat release zone and the heat absorption zone may be arranged independently of their geodetic position. In order to ensure a return transport of the liquid first phase change medium, provision is made in the heat pipe, e.g. on the inner wall, of capillary channels, which may be formed for example by a porous structure. Owing to the capillary effect, the capillary channels of the capillary structure bring about a transport of the liquid first phase change medium from the heat release zone to the heat absorption zone. The evaporated first phase change medium flows from the heat absorption zone to the heat release zone owing to a pressure drop which is being formed.

In some embodiments, the melting temperature of the second phase change medium is less than 20 K, or less than 10 K, greater than the evaporation temperature of the first phase change medium. In this way, it is ensured that, in the event of an increase in temperature in the thermal pipe, the second phase change medium begins to melt in a timely manner in order to prevent a further temperature increase. In this temperature range, the thermal pipe is still able to work, and so simultaneous heat transport into the latent heat store and through the thermal pipe is ensured. In this state, the cooling power of the cooling apparatus is particularly high and the capacity of the latent heat store is sufficient for a longer time period of a load peak than if the temperature increase were to render completely ineffective the effect of the thermal pipe owing to drying-out of the heat absorption zone.

However, even in an operating state in which the function of the thermal pipe fails, it is possible for the latent heat store to absorb the heat temporarily, with the result that the function of the thermal pipe is reestablished with a drop in the flow of heat from the heat source. In this case, a self-help system is advantageously involved. As long as the heat capacity of the latent heat store is not completely utilized, the latter protects a dried-out thermal pipe against damage owing to thermal overloading.

In some embodiments, the thermal pipe and the latent heat store are formed by two spatial structures nested one inside the other. For an exchange of heat between the thermal pipe and the latent heat store, a large surface is available, with the result that both a rapid introduction of heat into the latent heat store from the thermal pipe is possible in the event of load peaks occurring and the return of the heat into the thermal pipe from the latent heat store can be realized rapidly during normal operation. The cooling apparatus is therefore thermally stable even in the event of rapid load changes.

In some embodiments, the latent heat store is formed by a hollow spatial lattice. The second phase change material is enclosed in a hollow space which is formed as a latent heat store in the spatial lattice. The first phase change material is accommodated in lattice intermediate spaces formed by the lattice. The walls of the hollow lattice are thus provided as a separating wall between the first and second volumes. In this way, a large surface is available for the heat transfer. Furthermore, the lattice provides a relatively small cross section for the formation of the hollow space, with the result that the heat can rapidly spread into the interior of the second phase change material even in the case of relatively low heat conductivity.

In some embodiments, the latent heat source has a multiplicity of partial spaces, which are held in the thermal pipe. The partial spaces can be held in the thermal pipe by ribs, for example. Furthermore, it is possible for the partial spaces to be fluidically connected to one another. These fluidic connections, for example in the form of tubular connections, then simultaneously serve for holding the partial spaces of the latent heat store in the thermal pipe and facilitate the filling of the latent heat store with the second phase change medium. The division of the latent heat store into partial spaces increases the surface which is available for a transfer of heat between thermal pipe and latent heat store and the cooling device can therefore respond rapidly to load changing of the heat source.

In some embodiments, there are multiple thermal pipes, which are surrounded by the latent heat store. The thermal pipes are functional independently of one another. If, for example because of the occurrence of a locally limited load peak, one of the thermal pipes dries out, then the cooling power of the other thermal pipes is not affected by this. The latent heat store can, in this region, locally perform the cooling, and already release heat to adjacent thermal pipes, until the respective thermal pipe is made moist again by cooling and again assumes its function for cooling the overheated position. Consequently, the system is more robust with respect to the formation of local heat peaks (hot spots).

In some embodiments, in a heat release zone, the thermal pipe (or the thermal pipes) is (are) provided on the outside with a passive cooling structure. Passive cooling structures function according to the principle of surface enlargement and, in some embodiments, may consist for example of ribs or of a spatial lattice (or of ribs and a spatial lattice). The heat from the thermal pipe is then transferred to the passive cooling structure owing to the heat conduction, with the result that a relatively large surface is available for the radiation of heat into the surroundings. In this way, the cooling power of the cooling apparatus can be improved.

If the thermal pipe comprises a heat pipe, a capillary wall structure of the thermal pipe may be designed in one piece with the latter. This can be achieved for example by way of an additive manufacturing process in which the capillary wall structure is produced together with a solid wall structure, which seals off the volume of the thermal pipe hermetically with respect to the surroundings, in one and the same manufacturing run. Here, use is preferably made of the same construction material for the production of the capillary wall structure and the solid wall structure. A one-piece embodiment may provide a rapid transfer of heat between the solid and the capillary part of the wall.

In some embodiments, a heat-conducting structure is arranged in the latent heat store and is connected to the wall of the latent heat store. The connection to the wall firstly leads to mechanical fixing of the heat-conducting structure in the interior of the latent heat store. The connection to the wall also allows a transfer of heat between the heat-conducting structure and the wall of the latent heat store, with the result that heat can be introduced into, or discharged from, the second phase change medium (according to operating state) more rapidly. In some embodiments, the heat-conducting structure thus consists of a heat conductor which is better in comparison with the second phase change medium, said heat conductor may be composed of a metal or a metal alloy. In some embodiments, the heat-conducting structure comprises ribs and/or a spatial lattice.

In some embodiments, there is an electronic circuit having a structural component to be cooled, such as for example a power-electronic structural element, wherein the structural component is connected to the thermal interface of a cooling apparatus of the above-described type. In this way, with the operation of the electronic circuit, the advantages already discussed above are achieved, in particular that the cooling apparatus is able to be dimensioned in a relatively compact and light manner and the electronic circuit is nevertheless able to be cooled reliably if load peaks occur.

In some embodiments, the maximum possible cooling power of the thermal pipe of the cooling apparatus is greater than or equal to the heating power of the structural component at rated load of the structural component, with the result that, during normal operation, the cooling power of the thermal pipe is permanently sufficient for cooling. However, the cooling power is less than the heating power of the structural component at a permitted peak load, with the result that use is made of the latent heat store in the event of load peaks up to the permitted peak load occurring. The rated load and permissible peak load are characteristic values of the structural component. The magnitude of the permissible peak load is also dependent on the duration of the occurrence thereof, since the latent heat store provides only a particular heat capacity.

In some embodiments, there is a method for producing a cooling apparatus of the type specified above, wherein an additive manufacturing process is used for production. It is possible in particular for a laser melting process or a combination of laser sintering and laser melting to be used. However, for production, it is also possible for use to be made of other additive manufacturing processes, as discussed further in the following text.

Within the context of the present application, additive manufacturing processes are intended to be understood as meaning processes in which the material from which a component is intended to be produced is added to the component during the creation. In this case, the component is already created in its final form, or at least approximately in this form. The construction material may for example be of powder form or liquid form, with the material for producing the component being chemically or physically solidified by way of the additive manufacturing process.

In order to be able to produce the component, data describing the component (CAD model) are prepared for the selected additive manufacturing process. For the purpose of generating instructions for the manufacturing installation, the data are converted into data of the component that are adapted to the manufacturing process, in order that the suitable process steps for successively producing the component can proceed in the manufacturing installation. For this purpose, the data are prepared such that the geometrical data for the layers (slices) of the component that are to be produced in each case are available, this also being referred to as slicing.

As examples of additive manufacturing, reference may be made to selective laser sintering (SLS), selective laser melting (SLM), electron beam melting (EBM), laser metal deposition (LMD) and gas dynamic cold spray (GDCS). These processes are suitable in particular for the processing of metallic materials in the form of powders with which structural components can be produced.

In the case of SLM, SLS and EBM, the components are produced in layers in a powder bed. These processes are therefore also referred to as powder bed-based additive manufacturing processes. In each case, a layer of the powder is produced in the powder bed and is subsequently locally melted or sintered by the energy source (laser or electron beam) in those regions in which the component is intended to be created. The component is thus successively produced in layers and, following completion, can be removed from the powder bed.

In the case of LMD and GDCS, the powder particles are fed directly to the surface on which application of a material is intended. In the case of LMD, the powder particles are melted by a laser directly at the application point on the surface and in the process form a layer of the component to be produced. In the case of GDCS, the powder particles are intensely accelerated such that, with simultaneous deformation, they remain adhering to the surface of the component, primarily on account of their kinetic energy.

GDCS and SLS have in common the feature that the powder particles are not completely melted in these processes. In the case of GDCS, melting is realized at most in the peripheral region of the powder particles which, on account of the strong deformation at their surface, are able to fuse. In the case of SLS, when selecting the sintering temperature, care is taken to ensure that this is below the melting temperature of the powder particles. By comparison, in the case of SLM, EBM and LMD, the input of energy is deliberately of such a magnitude that the powder particles are completely melted.

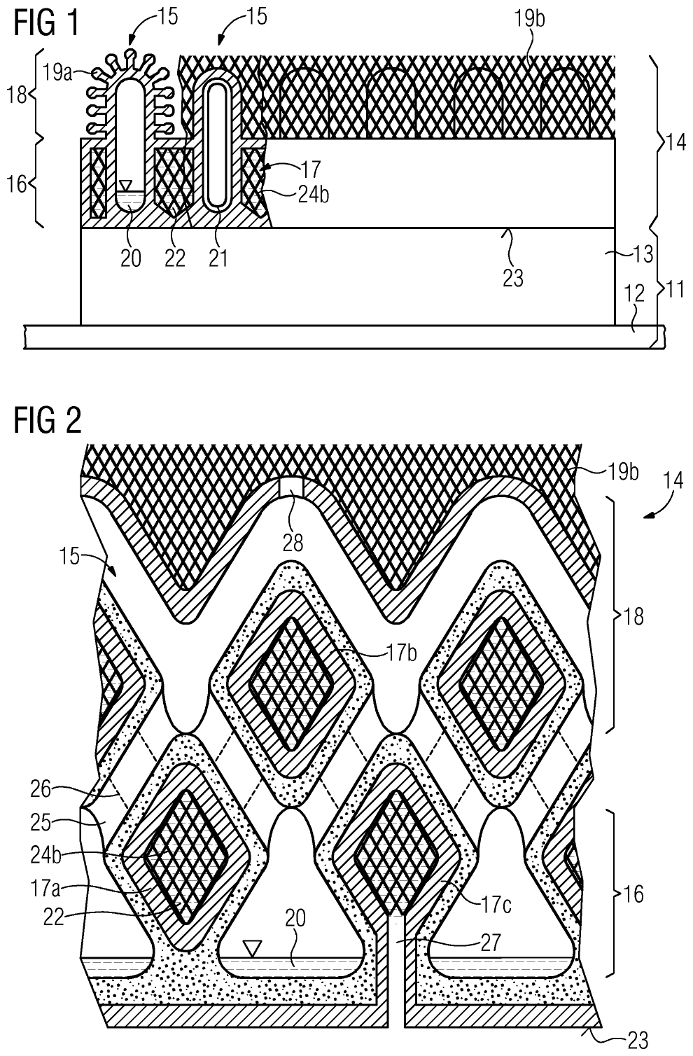

FIG. 1 illustrates an electronic assembly 11, which has a circuit carrier 12 and a structural component 13 in the form of a power-electronic structural element. Mounted on the structural component 13 is a cooling apparatus 14, which is illustrated, partially in section, in two variants. The two variants are separated from one another by a break line.

Both variants have thermal pipes 15, which are surrounded by a latent heat store 17 in a heat absorption zone 16. Furthermore, the thermal pipes 15 have heat release zones 18, which are surrounded by a passive cooling structure 19a in the form of ribs (variant illustrated to the left of the break line). Alternatively, it is also possible for a spatial lattice to be fitted as a passive cooling structure 19b, in the heat release zone 18 at the thermal pipe 15 (variant illustrated on the right).

The thermal pipes 15 are filled with a first phase change medium 20 (elementary gases, hydrocarbon compounds and metals with a low melting point all being possible, in dependence on the required operating temperature). The thermal pipe of one variant, illustrated on the left, is designed in the form of a thermosiphon, wherein the liquid first phase change medium 20 is collected in the heat absorption zone 16 and, when heated above the boiling point, evaporates. Said medium condenses in the heat release zone 18 and, owing to the force of gravity, flows back into the heat absorption zone 16. In some embodiments, as illustrated on the right in the second variant, the thermal pipe 15 may comprise a heat pipe. The thermal pipe 15 is then lined with a capillary wall structure 21, wherein the capillary forces in the capillary channels (not illustrated) of the capillary wall structure 21 flow to the heat absorption zone 16 and the evaporating first phase change medium 20 evaporates and flows to the heat release zone 18.

In contrast to the above-described thermosiphon, the use of heat pipes allows the cooling apparatus to also be used in installation positions differing from the one illustrated in FIG. 1.

In some embodiments, the latent heat store 17 is arranged around the heat absorption zone 16. Said latent heat store is filled with a second phase change medium 22 which, during normal operation of the structural component 13, remains solid (use being made of paraffins, salts or water, in dependence on the required operating temperature). Both the heat absorption zones 16 of the thermal pipes 15 and the latent heat store 17 are arranged in the vicinity of a contact surface 23 of the cooling apparatus 14, said contact surface serving as a thermal interface to the structural component 13, which functions as a heat source. In the event of the occurrence of thermal peak loads in the structural component 13, the cooling apparatus 14 is heated with greater intensity, such that the second phase change medium 22 in the latent heat store 17 starts to melt. This results in the thermal loading on the thermal pipes 15 being reduced. In order that the heat in the second phase change medium 22 can be distributed rapidly, provision is made in the latent heat store 17 of a heat-conducting structure in the form of a spatial lattice 24b, which is supported against the inner walls of the latent heat store 17.

In FIG. 2, the thermal pipe 15 consists of a single contiguous space. Accommodated therein are multiple partial spaces 17a, 17b, 17c (and further partial spaces not illustrated), which are connected to one another via connection structures 25. The connection structures 25 not only serve for fixing the partial spaces 17a, 17b, 17c but also may have connection channels 26, which are illustrated by dashed lines. In this way, the partial spaces 17a, 17b, 17c are able to be filled via an opening 27 with the second phase change medium 22. The opening is subsequently closed off in a manner not illustrated. The filling of the thermal pipe 15 with the first phase change medium 20 is realized by way of a further opening 28 which, likewise in a manner not illustrated, is closed off after the filling.

The division of the latent heat store into partial spaces 17a, 17b, 17c, and the interconnection thereof, gives rise to a spatial structure which is arranged in the thermal pipe 15 such that the thermal pipe likewise forms a spatial structure, which is nested with respect to the spatial structure of the latent heat store 17a, 17b, 17c. For a transfer of heat between the thermal pipe and the latent heat store, this gives rise to a relatively large surface, with the result that, in the event of peak loads, a transfer of heat can be realized not only via the contact surface 23 but also indirectly via the first phase change medium. It is also the case that subsequent cooling of the second phase change medium can, in this way, be realized in an advantageously rapid manner.

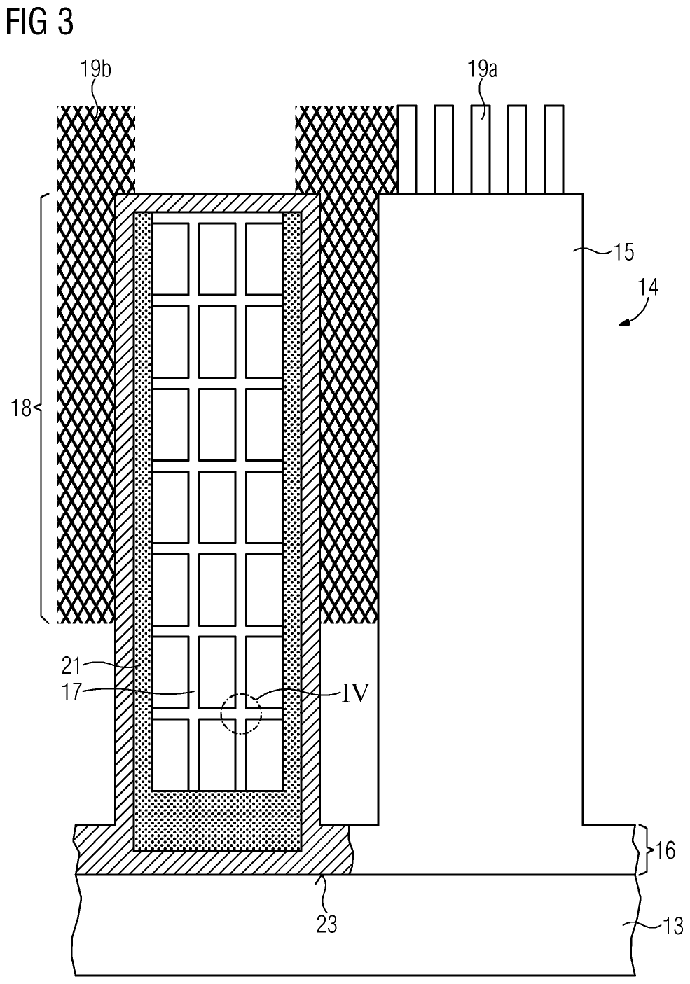

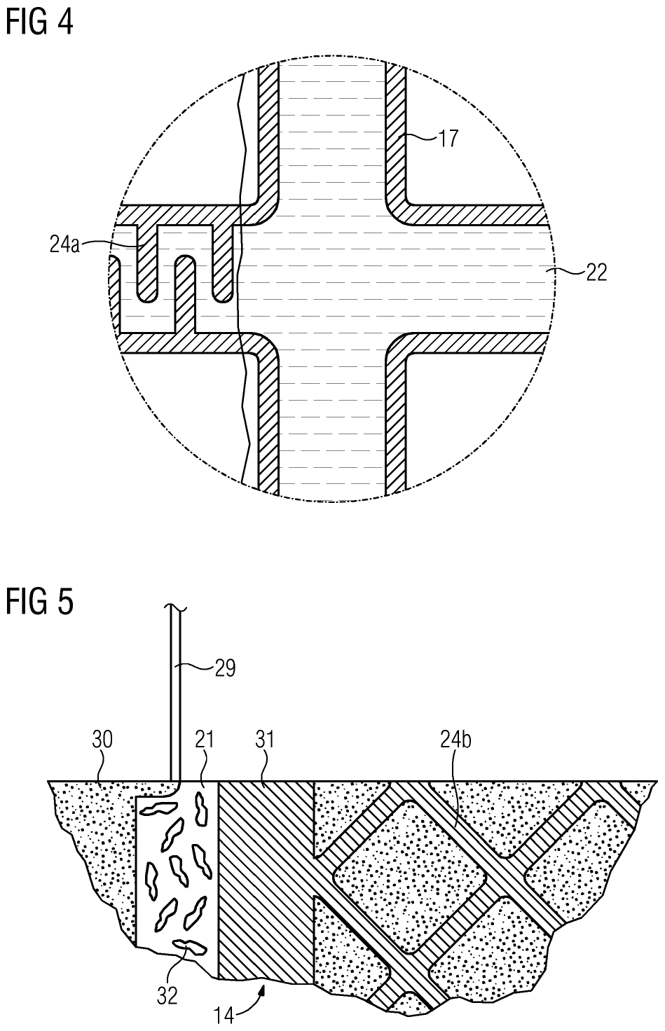

FIG. 3 illustrates individually standing thermal pipes 15 in the form of heat pipes, in the interior of which the latent heat store 17 is arranged in the form of a spatial lattice. As can be seen from the detail IV (illustrated in FIG. 4), said spatial lattice is of hollow design, with the second phase change medium 22 being accommodated in the hollow space. It is furthermore illustrated that heat-conducting structures 24a in the form of ribs may be accommodated in the hollow lattice. Said ribs are illustrated in one variant only, this being separated from the remainder of the detail IV by a break line. Alternatively, it is of course also possible for use to be made of a lattice structure, as illustrated in FIGS. 1 and 2 as 24b.

The thermal pipes 15 as per FIG. 3 furthermore have passive cooling structures in the form of lattices 19b and in the form of ribs 19a. As discussed above, these passive cooling structures 19a, 19b allow the release of heat from the thermal pipe 15 to the surroundings.

The structures illustrated in FIGS. 1 to 4 have a relatively complex geometry. In order to be able to produce said structures economically, it is possible for example for use to be made of a laser melting process and/or a laser sintering process as an additive manufacturing process. This is illustrated in FIG. 5. A laser beam 29 is directed at a powder bed 30, which is solidified in layers to form the structure of the component. The powder of the powder bed 30 remains in the intermediate spaces during the production. The production takes place in an installation which is suitable for this purpose and which is known per se and thus not illustrated in FIG. 5.

In order to produce a solid wall structure 31 of the thermal pipe and the heat-conducting structure 24b, the laser beam 29 is used for performing a selective laser melting process. In this case, melting of the powder in the powder bed 30 gives rise to solid component regions with a high density. The capillary wall structure 21 is produced directly by the laser beam 29, as illustrated in FIG. 5. In this case, use is made of a selective laser sintering process, in which the powder is not completely melted, and for this reason pores 32 remain in the capillary wall structure 21, which are thus formed by an open-pore pore system. Said pores allow the first phase change medium to be conducted, with the result that the functioning of a heat pipe is realized in the thermal pipe.

It is possible for the porosity to be formed such that it can be produced by way of a suitable exposure strategy, for example by means of selective laser melting (SLM) or selective laser sintering (SLS). Here, the pores can be obtained by way of a defined exposure strategy. On the one hand, it is possible for the porosity to be produced by SLS, that is to say by full-area input of energy, which is reduced in comparison with SLM. In this case, the powder particles sinter with one another, wherein intermediate spaces remain between the powder particles.

On the other hand, if, in the case of an SLS process being performed, the intermediate spaces between the powder particles do not give rise to sufficient porosity, it is also possible for an exposure strategy to be selected in which the surface of the powder bed is exposed only partially by SLM, with the result that individual powder particles can remain unexposed and be removed from the workpiece at a later stage. The pore formation can be produced by a statistically distributed, incomplete exposure of the powder bed, wherein the course of the pores or of the exposed region of the respective powder layers is random.

According to an alternative exposure strategy of the respective layer, the incomplete exposure regime follows particular patterns, for example a line spacing during the exposure, which line spacing is deliberately selected to be so large that unexposed and unmelted or unfused particles remain between the tracks. The desired pores are formed in said regions. This is achieved for example in that, during the production, the parallel tracks are rotated through for example 90° at regular intervals. This change takes place after a particular number of powder layers according to the desired pore size.

What is claimed is:

1. A cooling apparatus comprising:
a thermal interface for a heat source to be cooled;
a thermal pipe with a first phase change medium; and
a latent heat store with a second phase change medium;
wherein the first phase change medium and the second phase change medium are contained in respective volumes separated from one another;
wherein heat of the heat source, at the thermal interface, transfers into a heat absorption zone of the thermal pipe; and
a melting temperature of the second phase change medium is greater than an evaporation temperature of the first phase change medium.

2. The cooling apparatus as claimed in claim 1, wherein a difference between the melting temperature of the second phase change medium and the evaporation temperature of the first phase change medium is less than 20 K.

3. The cooling apparatus as claimed in claim 1, wherein the thermal pipe and the latent heat store are nested one inside the other.

4. The cooling apparatus as claimed in claim 3, wherein:
the latent heat store comprises a hollow spatial lattice;
the second phase change medium is enclosed in a hollow space in the spatial lattice; and
the first phase change medium is disposed in intermediate spaces formed by the lattice.

5. The cooling apparatus as claimed in claim 1, wherein the latent heat store comprises a multiplicity of partial spaces held in the thermal pipe.

6. The cooling apparatus as claimed in claim 5, wherein the partial spaces are in fluid communication with one another.

7. The cooling apparatus as claimed in claim 1, wherein there are multiple thermal pipes surrounded by the latent heat store.

8. The cooling apparatus as claimed in claim 1, wherein the thermal pipe comprises, in a heat release zone, a passive cooling structure.

9. The cooling apparatus as claimed in claim 8, wherein the passive cooling structure comprises at least one of ribs and a spatial lattice.

10. The cooling apparatus as claimed in claim 1, wherein the thermal pipe comprises a one piece body with a capillary wall structure.

11. The cooling apparatus as claimed in claim 1, further comprising a heat-conducting structure arranged in the latent heat store and connected to the wall of the latent heat store.

12. The cooling apparatus as claimed in claim 11, wherein the heat-conducting structure comprises at least one of ribs or a spatial lattice.

13. An electronic circuit comprising:
a structural component generating heat;
a thermal interface for the structural component;
a thermal pipe with a first phase change medium; and
a latent heat store with a second phase change medium;
wherein the first phase change medium and the second phase change medium are contained in respective volumes separated from one another;
wherein heat from the structural component, at the thermal interface, transfers into a heat absorption zone of the thermal pipe; and
a melting temperature of the second phase change medium is greater than an evaporation temperature of the first phase change medium.

14. The electronic circuit as claimed in claim 13, wherein the maximum possible cooling power of the thermal pipe of the cooling apparatus
is greater than or equal to the heating power of the structural component at rated load, but
is less than the heating power of the structural component at a permitted peak load.

15-17. (canceled)
